(19) United States
(12) Patent Application Publication
(10) Pub. No.: US 2009/0288861 A1
(43) Pub. Date: Nov. 26, 2009

(54) CIRCUIT BOARD WITH BURIED CONDUCTIVE TRACE FORMED THEREON AND METHOD FOR MANUFACTURING THE SAME

(75) Inventor: Guo Cheng LIAO, Kaohsiung County (TW)

Correspondence Address: LOWE HAUPTMAN HAM & BERNER, LLP, 1700 DIAGONAL ROAD, SUITE 300, ALEXANDRIA, VA, 22314, US

(73) Assignee: ADVANCED SEMICONDUCTOR ENGINEERING, INC., Kaohsiung (TW)

(21) Appl. No.: 12/422,629

(22) Filed: Apr. 13, 2009

(30) Foreign Application Priority Data
May 23, 2008 (TW) 097119024

(51) Int. Cl. H05K 1/02; H05K 3/00

(52) U.S. Cl. 174/255; 29/829

(57) ABSTRACT

A circuit board with a buried conductive trace formed thereon according to the present invention is provided. A buried conductive trace layer is formed on the surface of a substrate and the pads of the conductive trace layer are plated with a layer of copper so that the pads are heightened to facilitate the subsequent process of molding.

### CROSS REFERENCE TO RELATED APPLICATION

This application claims the priority benefit of Taiwan Patent Application Serial Number 097119024 filed May 23, 2008, the full disclosure of which is incorporated herein by reference.

### BACKGROUND OF THE INVENTION

1. Field of the Invention

The invention relates to a circuit board and the method for manufacturing the same and more particularly, to a circuit board with a buried conductive trace formed thereon and the method for manufacturing the same.

2. Description of the Related Art

Recently, as electronic devices have become multifunctional, technology for package substrates has been rapidly developed so as to realize lightweight, thin short, small, and highly integrated fine circuit patterns. In particular, such lightweight, thin, short, small, and highly integrated fine circuit patterns are required for the Chip Scale Package (CSP) product group. In order to form fine circuit patterns on a small substrate, a press method is typically used to form a buried conductive trace on the substrate.

Referring to FIGS. 1a to 1g, a conventional method for forming a buried conductive trace on a substrate is first to form a copper layer 120 on a carrier 110. The copper layer 120 has protrusion structures 122 and the pattern of the protrusion structures 122 is corresponding to that of the conductive trace desired to be formed on a substrate (see FIGS 1a and 1b). Afterward, the carrier 110 is pressed to a soft substrate 130, such as a B-stage Bismaleimide Triazine (BT) substrate so that the protrusion structures 122 of the copper layer 120 are buried on a surface 132 of the substrate 130. A surface 134 opposite to the surface 132 of the substrate 130 can be optionally pressed with another copper layer 140 having protrusion structures 142 so as to form a conductive trace on the surface 134 (see FIG. 1c). The carriers 110 are separated from the copper layers 120, 140 and the copper layers 120, 140 are then thinned by etching so that the surfaces 132, 134 of the substrate 130 are exposed and the structures 122, 142 still remain on and are flush with the surfaces 132, 134 of the substrate 130, respectively. The buried structures 122, 142 will finally form the conductive trace layers on the substrate 130 (see FIG. 1d).

Subsequently, through holes 150 are formed on the substrate 130 by etching or drilling and a copper layer 160 is formed on the surfaces 132, 134 of the substrate 130 and on the inner walls of the through holes 150 by electroless plating (see FIG. 1e). A layer of dry film 170 is then formed on the surfaces 132, 134 of the substrate 130 to act as a mask layer in such a manner that the conductive trace layer on the substrate 130, i.e. the buried structures 122, 142 is covered with the dry film 170 and the through holes 150 are exposed from the dry film 170. Next, the inner walls of the through holes 150 are plated with a copper layer 180 (see FIG. 1f). Afterward, the dry film 170 and the copper layer 160 formed on the surfaces 132, 134 of the substrate 130 by electroless plating are removed. Finally, a solder mask 190 is formed on the surfaces 132, 134 of the substrate 130 and the portion of the structures 122 to be used as pads to electrically connect to external circuitry are exposed from the solder mask 190. The exposed portion of the structures 122 are applied with a layer of organic solderability preservative (OSP) (see FIG. 1g).

With the above process, the resulting pad structures 122 are flush with the surface 132 of the substrate 130 and the solder mask 190 usually has a non-negligible thickness. Therefore, when the pad structures 122 are electrically connected to a chip by solder balls, the solder balls will have only a small portion of the thickness protruding from the solder mask 190 (not shown in the figure). As a result, this will lead to a small die gap between the chip and substrate 130. When an underfill material or molding compound is used to protect the chip in a subsequent package process, it is not easy to fill up the die gap with them. Thus, voids will be formed in the underfill material or molding compound in the die gap.

Accordingly, there exists a need to provide a method for manufacturing a circuit board with a buried conductive trace formed thereon to solve the above-mentioned problems.

### SUMMARY OF THE INVENTION

It is an object of the present invention to provide a method for manufacturing a circuit board with a buried conductive trace formed thereon, wherein the pads can be heightened by plating.

In order to achieve the above object, the method for manufacturing a circuit board with a buried conductive trace formed thereon according to the present invention is first to form a copper layer on a carrier. The copper layer has a plurality of protrusion structures and the pattern of the protrusion structures is corresponding to that of the conductive trace desired to be formed on a substrate. Afterward, the carrier is pressed to a B-stage BT substrate so that the protrusion structures of the copper layer are buried on a surface of the substrate. The carrier is separated from the copper layer and the copper layer is then thinned by etching so that the surface of the substrate is exposed and the protrusion structures still remain on and are flush with the surface of the substrate.

Subsequently, through holes are formed on the substrate and another copper layer is formed on the surface of the substrate and on the inner walls of the through holes by electroless plating. A layer of dry film is then formed on the surface of the substrate and exposes the pad areas and through holes. Next, the substrate is plated to form a copper layer on the pad areas and on the inner walls of the through holes. Afterward, the dry film and the copper layer formed on the surface of the substrate by electroless plating are removed. Finally, a solder mask is formed on the surface of the substrate and exposes the pad areas plated with the copper layer.

It is another object of the present invention to provide a circuit board manufactured by the above method.

According to the method of the present invention for manufacturing a circuit board with a buried conductive trace formed thereon, the pads are heightened by plating with a copper layer. When the pads are electrically connect to a chip by solder balls, the solder balls will protrude more from the solder mask. This will increase the die gap between the chip and the substrate. Consequently, it is easier for the underfill material or molding compound to flow to and fill up the die gap in the package process. Thus, voids will not be formed in the underfill material or molding compound in the die gap. Moreover, since the through holes and pads can be plated with a copper layer in a common process, there is no need to perform additional plating process in order to heighten the pads. It just needs to form additional openings on the dry film to expose the pad areas therefrom.

The foregoing, as well as additional objects, features and advantages of the invention will be more readily apparent from the following detailed description, which proceeds with reference to the accompanying drawings.

### BRIEF DESCRIPTION OF THE DRAWINGS

FIGS. 1a to 1g illustrate a conventional method for manufacturing a circuit board with a buried conductive trace formed thereon.

FIGS. 2a to 2g illustrate the method for manufacturing a circuit board with a buried conductive trace formed thereon according to the present invention.

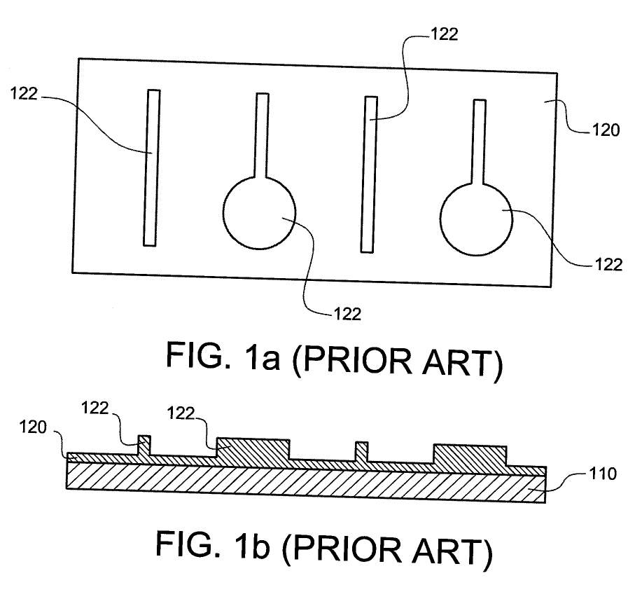

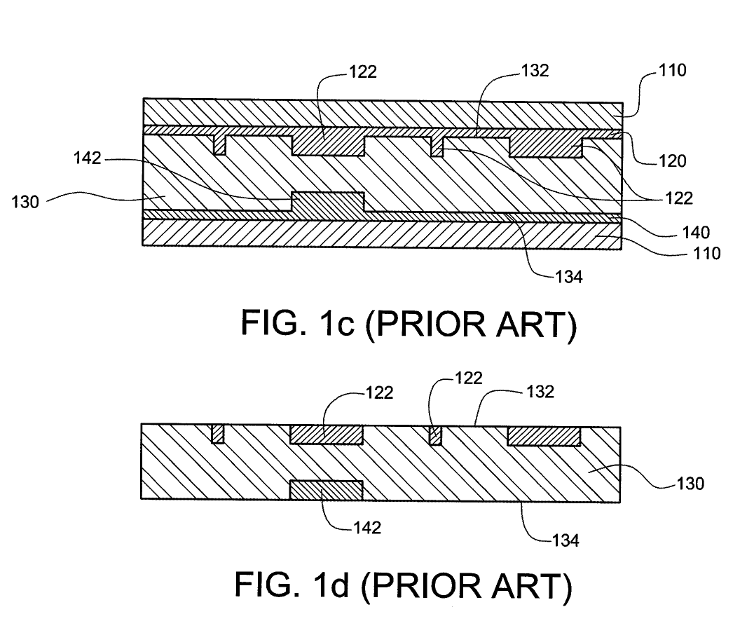

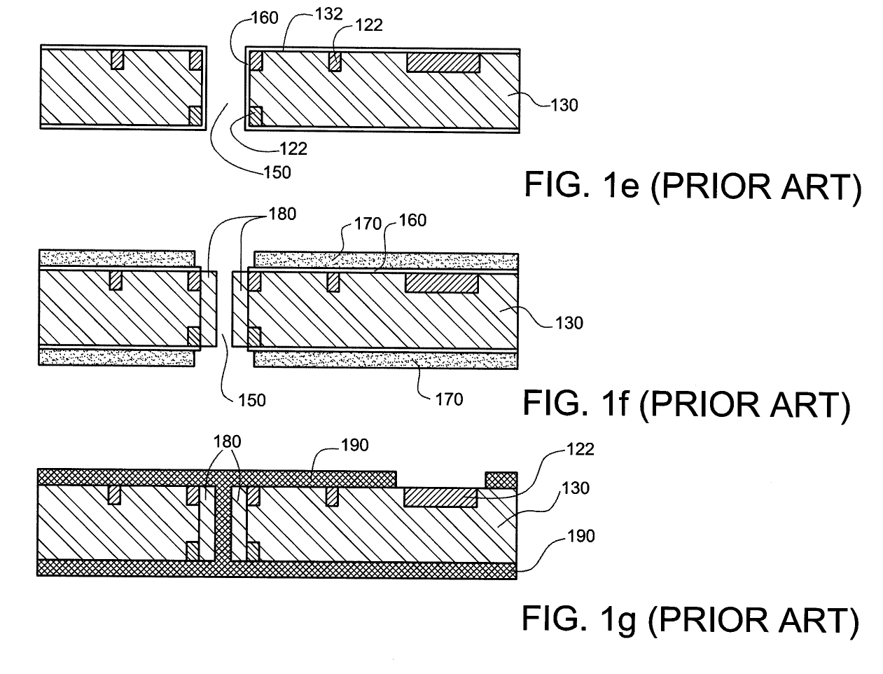

### DETAILED DESCRIPTION OF THE PREFERRED EMBODIMENT

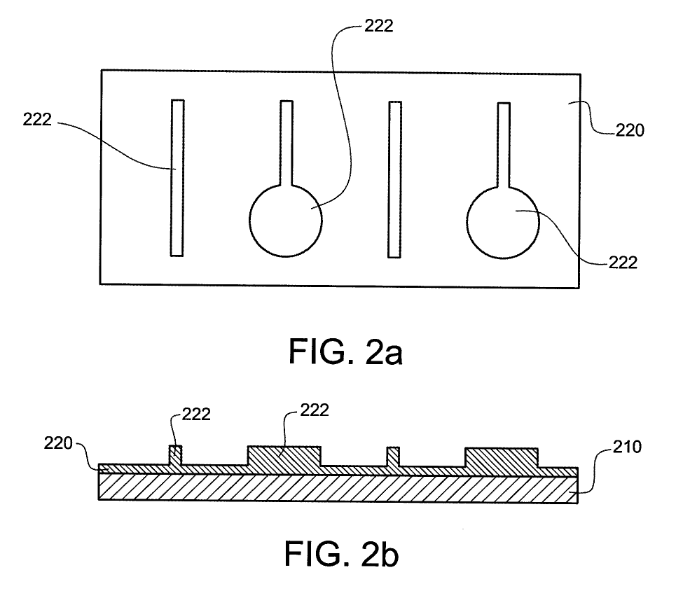

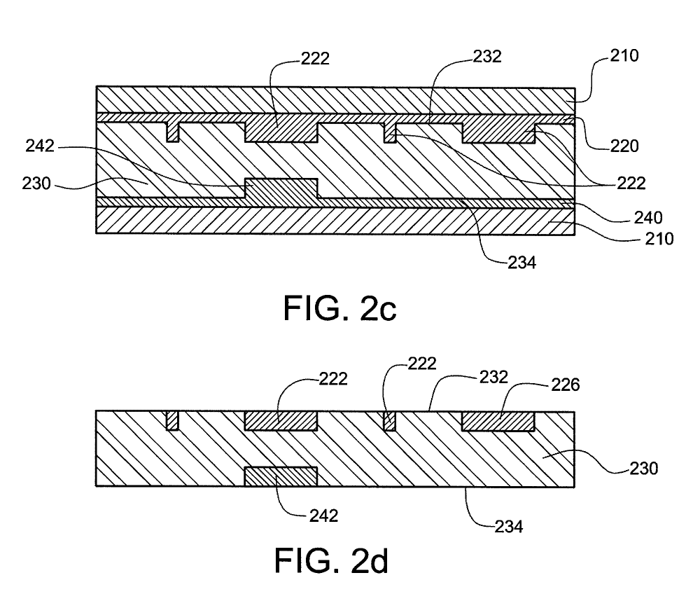

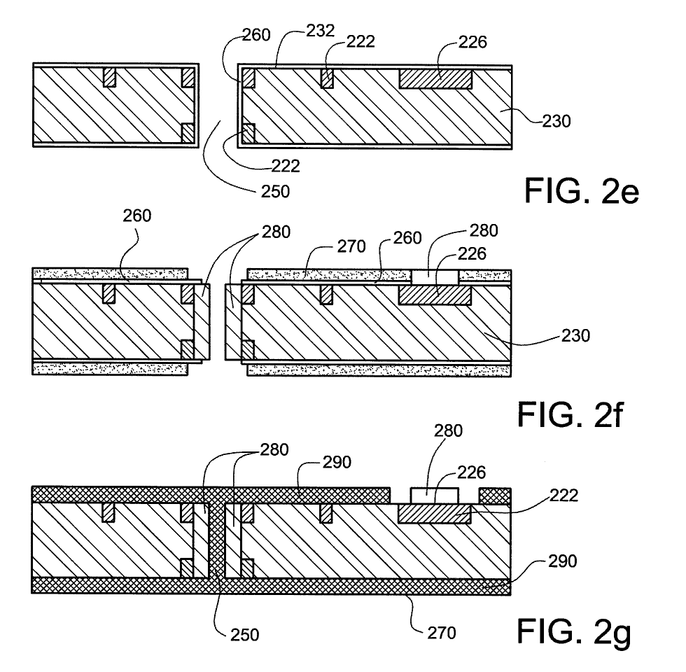

Referring to FIGS. 2a to 2g, the method for manufacturing a circuit board with a buried conductive trace formed thereon according to the present invention is first to form a metal layer 220, such as a copper layer on a carrier 210. The copper layer 220 has a plurality of protrusion structures 222 and the pattern of the protrusion structures 222 is corresponding to that of the conductive trace desired to be formed on a substrate (see FIGS. 2a and 2b). Afterward, the carrier 210 is pressed to a soft substrate 230, such as a B-stage Bismaleimide Triazine substrate so that the protrusion structures 222 of the copper layer 220 are buried on a surface 232 of the substrate 230. A surface 234 opposite to the surface 232 of the substrate 230 can be optionally pressed with another copper layer 240 having protrusion structures 242 so as to form a conductive trace on the surface 234 (see FIG. 2c). The carriers 210 are separated from the copper layers 220, 240 and the copper layers 220, 240 are then thinned by etching so that the surfaces 232, 234 of the substrate 230 are exposed and the structures 222, 242 still remain on and are flush with the surfaces 232, 234 of the substrate 230, respectively. The buried structures 222, 242 will finally form the conductive trace layers on the substrate 230. The exposed surfaces of a portion of the buried structures 222 are defined as areas 226, which are large enough to be able to be electrically connected to external circuitry, such as a chip (see FIG. 2d).

Subsequently, through holes 250 are formed on the substrate 230 by etching or drilling and a copper layer 260 is formed on the surfaces 232, 234 of the substrate 230 and on the inner walls of the through holes 250 by electroless plating (see FIG. 2e). A layer of dry film 270 is then formed on the surfaces 232, 234 of the substrate 230 to act as a mask layer and exposes the areas 226 and through holes 250. Next, the substrate 230 is plated to form a metal layer 280, such as a copper layer on the areas 226 and on the inner walls of the through holes 250 (see FIG. 2f). Afterward, the dry film 270 and the copper layer 260 formed on the surfaces 232, 234 of the substrate 230 by electroless plating are removed. Finally, a solder mask 290 is formed on the surfaces 232, 234 of the substrate 230 and exposes the areas 226 plated with the copper layer 280. The areas 226 are then applied with a layer of organic solderability preservative. The resulting circuit board with a buried conductive trace formed thereon according to the present invention is illustrated in FIG. 2g.

The circuit board of the present invention includes the substrate 230, which has the through holes 250 plated with the copper layer 280. The conductive trace layer 222 is buried on the substrate 230 and exposed from the surface 232. The conductive trace layer 222 has the areas 226 flush with the surface 232 of the substrate 230. The copper layer 280 is formed on the areas 226 to protrude from the surface 232 of the substrate 230. In addition, the solder mask 290 is formed on the surface 232 of the substrate 230 and exposes the copper layer 280 on the areas 226.

According to the method of the present invention for manufacturing a circuit board with a buried conductive trace formed thereon, the areas 226 are used as pads and heightened by plating with the copper layer 280. When the areas 226 are electrically connect to external circuitry, such as a chip by solder balls, the solder balls will protrude more from the solder mask 290 as compared with the above conventional circuit board (not shown in the figure). This will increase the die gap between the chip to be bonded and the substrate 230. Consequently, it is easier for the underfill material or molding compound to flow to and fill up the die gap in the package process. Thus, voids will not be formed in the underfill material or molding compound in the die gap. Moreover, since the through holes 250 and pad areas 226 can be plated with the copper layer 280 in a common process, there is no need to perform additional plating process in order to heighten the pad areas 226. It just needs to form additional openings on the dry film 270 to expose the pad areas 226 therefrom and therefore does not increase the production cost and introduce additional plating process.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A method for manufacturing a circuit board, comprising the steps of:
providing a substrate with a first surface and a second surface opposite to the first surface;
forming a buried conductive trace layer on the first surface of the substrate, the buried conductive trace layer having a first area exposed from the first surface of the substrate;
forming a mask layer on the first surface of the substrate and exposing the first area of the buried conductive trace layer;
plating the substrate to form a second copper layer on the first area of the buried conductive trace layer;
removing the mask layer from the substrate; and
forming a solder mask on the first surface of the substrate and exposing the second copper layer.

2. The method as claimed in claim 1, further comprising:
forming a through hole on the substrate,
wherein the mask layer exposes the through hole and the through hole is plated with the second copper layer.

3. The method as claimed in claim 1, wherein the first area of the buried conductive trace layer is flush with the first surface of the substrate after the buried conductive trace layer is formed on the first surface of the substrate.

4. The method as claimed in claim 1, wherein the step of forming the buried conductive trace layer on the first surface of the substrate comprises:
providing a carrier;
forming a first copper layer with a plurality protrusion structures on the carrier;
pressing the carrier to the substrate so that the protrusion structures of the first copper layer are buried on the first surface of the substrate;
removing the carrier; and
thinning the first copper layer to have the first surface of the substrate exposed.

5. The method as claimed in claim 4, wherein the first copper layer is thinned by etching.

6. The method as claimed in claim 1, wherein the mask layer is a dry film.

7. The method as claimed in claim 2, further comprising:
plating the substrate to form a third copper layer on the first surface of the substrate and on the through hole before the mask layer is formed on the first surface of the substrate; and
removing the third copper layer from the first surface of the substrate after the second copper layer is formed on the first surface of the substrate.

8. A circuit board, comprising:
a substrate having a first surface;
a conductive trace layer buried on the substrate and exposed from the first surface of the substrate, wherein the conductive trace layer has a first area;
a metal layer formed on the first area of the conductive trace layer and protruding from the first surface of the substrate; and
a solder mask formed on the first surface of the substrate and exposing the metal layer.

9. The circuit board as claimed in claim 8, wherein the substrate has a through hole plated with a copper layer.

10. The circuit board as claimed in claim 8, wherein the first area is flush with the first surface of the substrate.

11. The circuit board as claimed in claim 8, wherein the metal layer is a copper layer.
